(19) United States
(12) Patent Application Publication
(10) Pub. No.: US 2003/0159101 A1
(43) Pub. Date: Aug. 21, 2003

(54) Cyclic redundancy code generator

(76) Inventors: Kevin J. Hyland, Dublin (IE); Vincent G. Gavin, Galway (IE)

Correspondence Address: NIXON & VANDERHYE P.C., 8th Floor, 1100 North Glebe Rd., Arlington, VA, 22201-4714, US

(21) Appl. No.: 09/932,927

(22) Filed: Aug. 21, 2001

(30) Foreign Application Priority Data
Jul. 24, 2001 (GB) 0117960.5

(51) Int. Cl. H03M 13/00

(52) U.S. Cl. 714/781

(57) ABSTRACT

A cyclic redundancy code generator for data packets without an inter-packet gap comprises a CRC generator which divides each packet by a generator polynomial of degree n wherein n and augmenting logic which divides, by the generator polynomial, the product of the intermediate remainder and the term of order n in the generator polynomial, whereby each packet is padded without zeros

### CROSS-REFERENCE TO RELATED APPLICATION

Ser. No. 09/321,185 filed May 27, 1999 for Myles Kimmitt entitled ‘High Speed Generation and Checking of Cyclic Redundancy Check Values’ and commonly assigned herewith.

### FIELD OF THE INVENTION

The present invention relates to the generation and checking of cyclic redundancy code values. The invention is particularly concerned with such operations performed in the processing of data packets which are usually provided with a cyclic redundancy check (CRC) field computed on the basis of the content of the packet and then appended to the packet.

### BACKGROUND TO INVENTION

Cyclic redundancy checking is a well known method of error detection and/or correction in transmission and storage systems, redundant bits are added to the message or data block, the amount of which is dependent on the degree of detection and/or correction desired

The CRC used in a preferred form of this invention is defined for the ANSI/IEEE Std 802 family of LAN standards In that standard, a 32 bit CRC value is loaded into the Frame Check Sequence (FCS) field of a data packet when transmitted The CRC is calculated as a function of the contents of the packet

In some circumstances, it is possible to organise the cyclic redundancy check generation so that if the check is valid, a string of zeros is produced Then error detection relies on the interpretation of the relevant syndrome, having non zero bits related to the error or errors However, it is desirable in order to avoid confusion with other coded sequences or to avoid producing a string of zeros in a packet processing system, to arrange, as indicated in the aforementioned standard, an offset so that the correct application of the cyclic redundancy check produces an original specified value if the check is valid

Consider a packet of length k bits. It can be represented as a polynomial f(x) of degree k−1 For example

f(x)=10100100=x⁷+x⁵+x²

f(x)=101001=x²+x³+1 *

The CRC value for ANSI/IEEE 802 is defined by the following generating polynomial.

G(x)=x³²+x²⁶+x²³+x²²+x¹⁶+x¹²+x¹¹+x¹⁰+x⁸+x⁷+x⁵+x⁴+x²+x+1

A standard way of generating the CRC value for any given data unit is defined in the following points

(a) The first 32 fits of the packet are complemented

(b) The k bits of the packet are then considered to be the coefficients of a polynomial f*(x) of degree k−1 as explained above

(c) f*(x) is multiplied by x³² This has the effect of augmenting the data payload with 32 trailing bits of zero

(d) The result is then divided by G(x) using modulo-2 arithmetic, producing a remainder R(x) of degree less than or equal to 31 The coefficients of R(x) are written as a 32 bit sequence which, when complemented, are the CRC's value placed in the FCS field

In padding the packet out with 32 trailing zeros, one ensures that when the 32-bit remainder (i e the CRC) is subtracted from the augmented payload (x³²f*(x)), to yield a new payload divisible by G(x) in the case of no errors, the original data is not affected

The action of padding out the packet with 32 trailing bits of zero has hitherto been implemented using a state machine upstream of the CRC generating logic. Such a state machine controls the amount of zeros, or inter-packet-gap (IPG), between two successive packets The present invention implements this padding out with zeros using simple logic In essence, an intermediate CRC is calculated from a packet with no trailing zeros (i e is an immediate succession of packets) and the result is modified to appear to have come from an augmented packet

It is feasible to perform the invention in respect of an immediate succession of packets (i e with no inter-packet gap) in serial form employing for example a linear feedback shift register with exclusive-OR gates to perform division and registers to hold intermediate values. The 74F401 CRC Generator/Checker made by Fairchild Semiconductor Corporation is one example Preferably however the invention is performed in a manner resembling that described in Kimmitt, supra, on packets which are presented in parallel-byte form, i e comprising a succession of segments each comprising one or more bytes Typically each segment except for either the first or last of a packet (depending on the alignment of the packet) would consist of eight bytes or such other plurality of bytes as may be selected Such parallel byte transmissions are accompanied by control words that identify the contemporary bytes as the start or finish of the packet and validity bytes that indicate which bytes in the segment are value bytes

Further features of the invention will become apparent from the detailed description which follows, with reference to the drawings

### BRIEF DESCRIPTION OF THE DRAWINGS

FIG. 1 illustrates a known method of generating cyclic redundancy code

FIG. 2 is a diagram illustrating the general scheme for a CRC generator according to the invention

FIG. 3 illustrates a specific embodiment of the invention

FIG. 4 illustrates one embodiment of a CRC generating system according to the invention

FIG. 5 illustrates another embodiment of the invention

FIG. 6 illustrates another embodiment of the invention

### DETAILED DESCRIPTION

A standard parallel implementation of a CRC generator is as follows

Consider a packet of length k-bits represented by the polynomial f(x) as previously mentioned To adopt a standard level of parallelism, the packet can be grouped into smaller sequences a₁(x) of length j, formed by the recursive equation.

Packet b₀ b₁ bₕ₂ K bₕ₋₁ (by convention, b₀ is the first bit of the first byte)

$$\begin{matrix}f ( \text{?} ) = {b}_{\text{?}} {\text{?}}^{\text{?} \text{?}} + {b}_{\text{?}} {x}^{\text{?} \text{?}} + K + {b}_{k - 2} x + {b}_{k - 1} \\ = {\sum }_{i = \text{?}}^{{k}_{i - 1}} {x}^{k - \text{?} \text{?} - \text{?} \text{?}} {a}_{\text{?}} ( x )\end{matrix}$$

$$\text{?} \text{indicates text missing or illegible when filed}$$

Where

[symbol]

With the restrictions 1≦ₗ≦k and k is an integer.

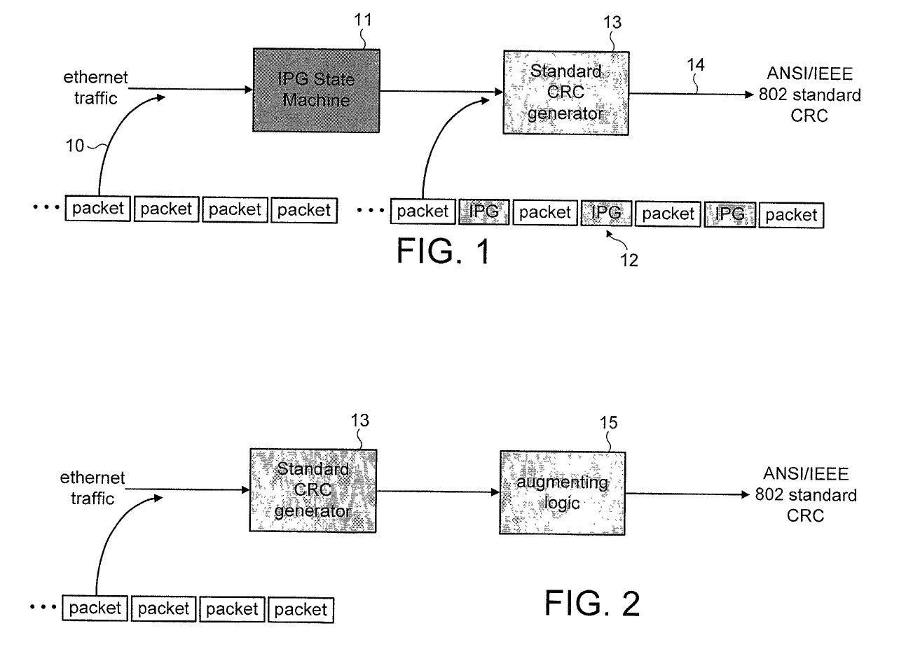

A standard CRC generator is shown in FIG. 1 In that (known) example ‘Ethernet traffic’ 10 (a succession of packets) is received by an IPG state machine 11 which generates an inter-packet-gap between each successive pair of packets, the packets 12 separated by the gaps being received by a standard CRC generator 13 to provide an output 14 in which the packets have been augmented by a CRC field

The standard CRC generator may accept j bits (j>1) at a time and recursively calculate the remainder over the packet This can produce difficulty if the length of the packet (k bits) is not an integral multiple of j This difficulty (shared by the invention) can be resolved as discussed later on

Using an augmenting technique according to the invention, the CRC is preferably calculated in two steps First, all the data is processed in a CRC generator 13 to calculate an intermediate remainder rₐ(x), which is input to an augmenting logic block 15 as shown in FIG. 2 Note that the data is processed as it arrives No attempt has been made to pad it out with zeros Second, a true remainder r(x) is calculated from the intermediate remainder by posing the question, if that is the remainder of f(x) divided by G(x), what would be the remainder of x³²f(x) divided by G(x)⁹ The answer is found by finding the remainder of N³²r_{d}(x) divided by G(x)

In essence, this two step approach can be sumarised in the following equations

$$\begin{matrix}\frac{f ( x )}{G ( x )} = {q}_{\text{?}} ( x ) + \frac{{r}_{\text{?}} ( x )}{G ( x )} & [ Step 1. recursive ] \\ \frac{{x}^{\text{?}} {r}_{\text{?}} ( x )}{G ( x )} = {q}_{\text{?}} ( x ) + \frac{r ( x )}{G ( x )} \\ \text{?} \text{indicates text missing or illegible when filed} & [ Step 2 terminating ]\end{matrix}$$

where q_{d}(x) and q_{b}(x) are the whole results of the division and of no interest

So, for every j bits of the message, the intermediate CRC is calculated thus

$${r}_{1} ( x ) = R [ \frac{{a}_{\text{?}} ( x ) + {\text{?}}^{} {\text{?}}_{} ( x )}{G ( x )} ]$$

$${r}_{2} ( x ) = R [ \frac{{a}_{1} ( x ) + {x}^{\text{?}} {r}_{1} ( x )}{G ( x )} ]$$

$$\text{?} \text{indicates text missing or illegible when filed}$$

$$\begin{matrix}{r}_{\text{?} - 1} ( x ) = R [ \frac{{a}_{\text{?}} ( x ) + {x}^{\text{?}} {r}_{\text{?}} ( x )}{G ( x )} ] & ( 1 ) \\ {r}_{k \text{?} 1} ( x ) = R [ \frac{{a}_{k \text{?} i - 1} ( x ) + {x}^{\text{?}} {r}_{k \text{?} i - 1} ( x )}{G ( x )} ] \\ \text{?} \text{indicates text missing or illegible when filed} & ( 2 )\end{matrix}$$

Note r₀(x)=I(x)=0×9226 F562, is the standard offset value prescribed in the IEEE standard

After all bits have been subjected to the recursive operation, the output is the intermediate remainder

r_{d}(x)=rₕ₁(x)

To implement the first stage one may separate out the terms in equation 1 above and find that

$$\begin{matrix}{r}_{i - 1} ( x ) = R [ \frac{{a}_{\text{?}} ( x ) \text{?} {x}^{\text{?}} {r}_{\text{?}} ( x )}{G ( x )} ] \\ = R [ \frac{{a}_{\text{?}} ( x )}{G ( x )} ] + R [ \frac{{x}^{\text{?}} {r}_{\text{?}} ( x )}{G ( x )} ] \\ = A [ {a}_{\text{?}} ( x ) ] + B [ {r}_{\text{?}} ( x ) ]\end{matrix} \\ \text{?} \text{indicates text missing or illegible when filed} \qquad ( 3 )$$

One may consider A[a₁(x)] to be the forward terms and B[r₁(x)] the reverse terms of a hardware implementation If the number of bits to be processed at a time, j, were equal to the number of bits in the CRC, namely 32, one could apply a further simplification This holds true if the number of bits being processed in parallel is less than the number of bus in the CRC also i e if the degree of f(x) is less than or equal to the degree of g(x)=>R[f(x)/g(x)|=f(x)

Adopting this one produces

$$\begin{matrix}{r}_{i - 1} ( x ) = A [ {a}_{\text{?}} ( x ) ] + B [ {r}_{\text{?}} ( x ) ] \\ = {a}_{\text{?}} ( x ) + B [ {r}_{\text{?}} ( x ) ]\end{matrix}$$

$$\text{?} \text{indicates text missing or illegible when filed}$$

Were the data padded out with zeros, as is usually the case, this would be the CRC However, since this is not the case with this approach there is one final step to calculate the true CRC value

If 1>n, then the true remainder, or CRC is

$$r ( x ) = R [ \frac{{x}^{} {r}_{k 1} ( x )}{G ( x )} ] \\ \text{?} \text{indicates text missing or illegible when filed} \qquad ( 4 )$$

This is the terminating stage

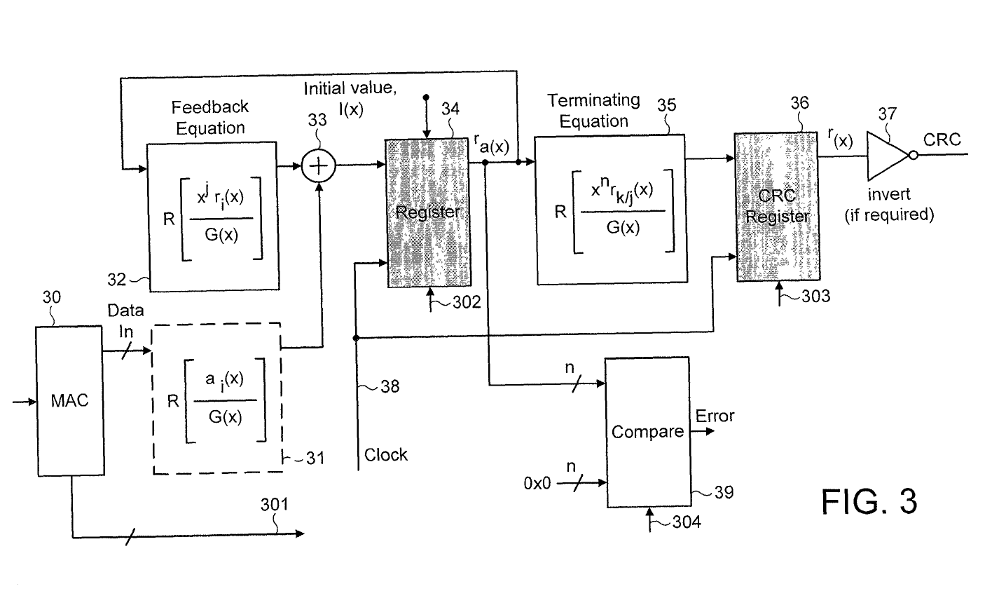

FIG. 3 illustrates a hardware implementation of a CRC generator according to the invention This example is a two-stage pipelined generator with j=64 and the CRC computed as 32 bits wide

In the embodiment shown in FIG. 3, input data in 8-byte parallel form is received on parallel lines (in this case 64) lines from a media access control (MAC) device 30 The forward terms are computed in stage 31 and the reverse terms are computed in stage 32, the sum being formed by a multiplicity of exclusive-OR circuits, as explained later, represented for simplicity by the single exclusive-OR symbol 33, the result is put in register 34 The terminating equation is computed by stage 35 and put into CRC register 36 If desired (as is conventional) the result is inverted by inverters 37 to yield the CRC

A check over the intermediate CRC may be made by comparing rₐ(x) with 0×0 in comparator 39 to produce an error signal if there is a non-zero difference

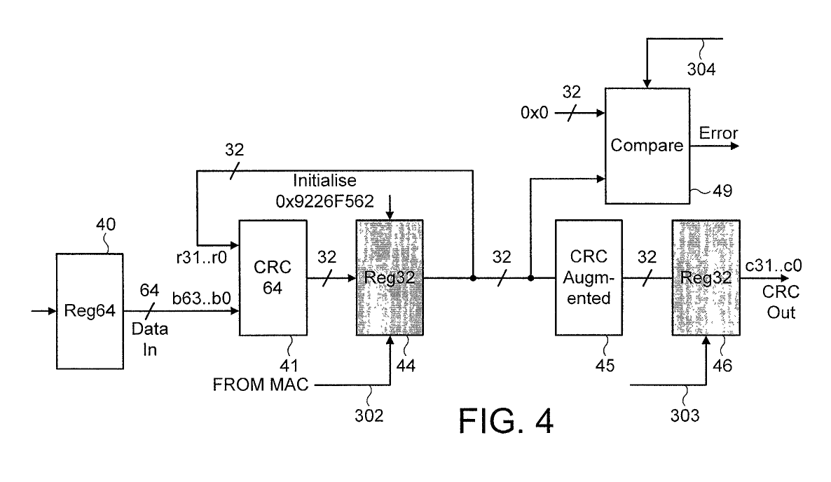

FIG. 4 includes an input 64-bit register 40 followed by a CRC (generator) 41 which performs the functions of stages 31, 32 and 33 in FIG. 3 to produce a 32-bit CRC value which is put into a 32-bit register 44 Stages 45, 46 and 49 correspond to stages 35, 36 and 39 in FIG. 3

In this (parallel) implementation, the terminating equations defining the augmenting function operate on all the remainders presented by register 34 It is accordingly necessary to sample the output of the CRC register at an appropriate time, in this example one clock ‘tick’ after the MAC 30 identifies an ‘End of Frame’ (EOF) control word that conventionally accompanies a packet

A similar control needs to be exercised in this embodiment on register 34 to determine whether to feedback the initial ‘seed’ value I (x) or the output of adder 33 to the recursive block 32 The control may again be derived from the MAC 30 When the MAC detects a Start of Frame control word it will cause the register 34 to feedback the initial value, otherwise the register feeds back the output of the adder

The control exercised by the MAC is denoted by lines 301. The corresponding control exerted on registers 34 and 36 is denoted by lines 302 and 303 The comparison performed by comparator 39 is preferably also controlled by the MAC, as denoted by line 304

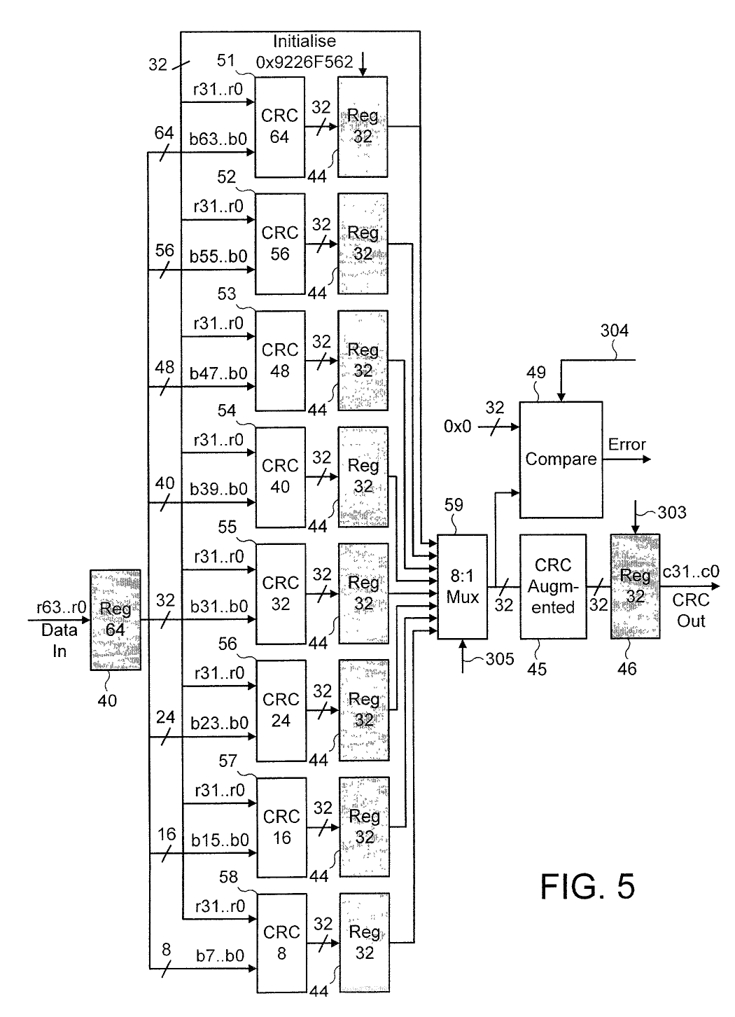

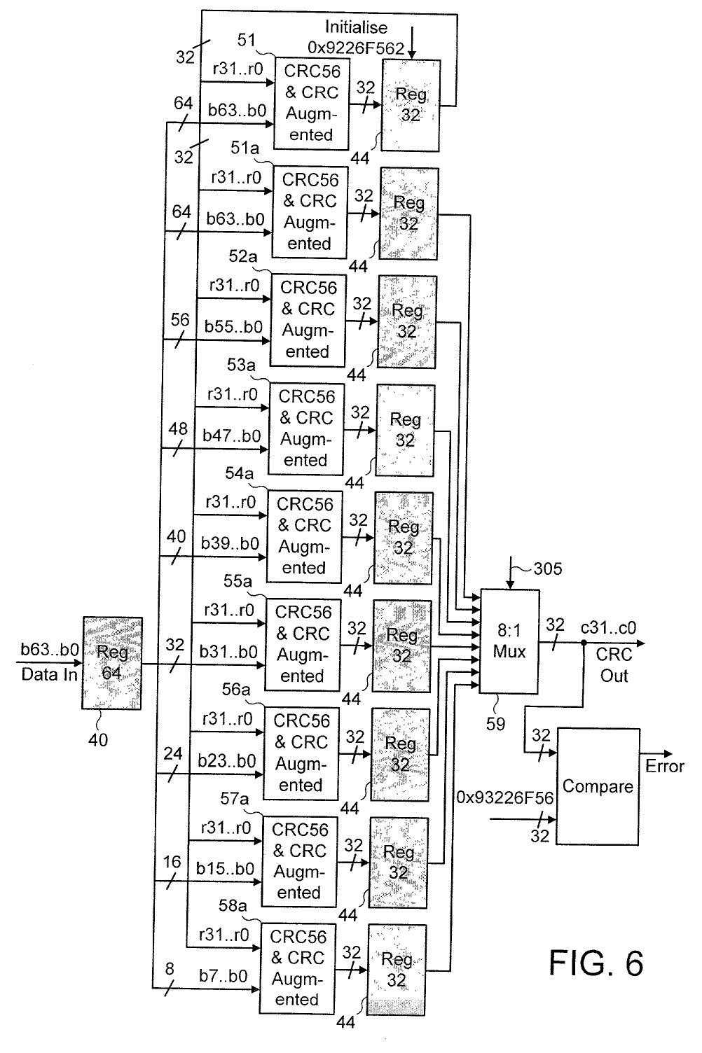

As is remarked earlier, a restriction on the algorithm that the total number of bits in the message, k, must be divisible by the number being processed in parallel, j, the consequence is restriction on the application requiring the CRC For example in data communications, packets seldom have a fixed length Often, the number of bits being processed in parallel is 64 i e 8 bytes However, packets are not always integer multiples of 8 bytes in length In fact, the last 8 byte block of the packet could have 1, 2. 8 bytes of valid data present So as not to limit the amount of data that could be processed in parallel to 1 byte, the recursive equation defined by equation 2 and implemented as CRC 64 in FIG. 4, is modified seven times and each modification incorporated into the design to deal with each of the terminating cases The CRC is calculated for each of the terminating cases in parallel and the correct one chosen by a MUX, controlled by a bus indicating the amount of valid bytes in each of the 8 byte This is shown in FIGS. 5 and 6

FIG. 5 illustrates partly the multiplication of the stages 8-fold The register 40 is coupled not only to 64-bit CRC generator 51 but also to seven other CRC generators 52 to 58 all of which receive a 32-bit feedback but compute the forward terms on the bits belonging to successively smaller numbers of the input bytes Thus CRC 56 operates on bits b55 60. CRC 48 on bits b47-60 and so on Each of the eight registers 44 is initialised with the same I(x) One of the intermediate CRC values is selected by means of an 8 1 multiplexer 59, the selected value being coupled to stages 45, 46 and 49 as in FIGS. 3 and 4

In this embodiment, the control for the multiplexer may be obtained from the MAC 30, and is schematically represented by line 305 Accompanying any packet is (normally) a control signal that identifies the valid bytes in each 8-byte segment of the packet Depending on the alignment of the packet, the first or last segment may have fewer than 8 valid bytes The amount of valid data observed when the EOF control word identifies the last segment of a packet dictates which remainder is selected by the multiplexer 59

CRC generator equations suitable for the generators 51 to 58 follow Each generator comprises a multiplicity of exclusive-OR gates for generating the outputs from selected bits of the forward and reverse terms In this example an array of 2-input exclusive-OR gates is employed, so several levels of gating are (in general) required

For example, output bit [0] of the 8-bit CRC generator 58, this bit being denoted crc8_{—}0, is generated by a single XOR gate having inputs r2 and r8, (i e bits [2] and [8] of the reverse terms But [19], denoted crc24_{—}19, output from the 24-bit CRC generator 56 requires several stages or levels of 2-input XOR gates which operate on bit [b11] of the input and bits [2], [5-6], [10-11], [14], [17-19] and [21-23] of the feedback bits

8-bit CRC Equatious

| | |
|---|---|
| Number of 2-input exclusive-or gates: | 114 |
| Maximum number of terms: | 8 |
| Maximum Levels: | 3 |

| | |
|---|---|
| crc8_0 = | r2 + r8. |
| crc8_1 = | r0 + r3 + r9. |
| crc8_2 = | r0 + r1 + r4 + r10. |
| crc8_3 = | r1 + r2 + r5 + r11. |
| crc8_4 = | r0 + r2 + r3 + r6 + r12. |
| crc8_5 = | r1 + r3 + r4 + r7 + r13. |
| crc8_6 = | r4 + r5 + r14. |
| crc8_7 = | r0 + r5 + r6 + r15. |
| crc8_8 = | r1 + r6 + r7 + r16. |
| crc8_9 = | r7 + r17. |
| crc8_10 = | r2 + r18. |
| crc8_11 = | r3 + r19. |
| crc8_12 = | r0 + r4 + r20. |
| crc8_13 = | r0 + r1 + r5 + r21. |
| crc8_14 = | r1 + r2 + r6 + r22. |
| crc8_15 = | r2 + r3 + r7 + r23. |
| crc8_16 = | r0 + r2 + r3 + r4 + r24. |
| crc8_17 = | r0 + r1 + r3 + r4 + r5 + r25. |
| crc8_18 = | r0 + r1 + r2 + r4 + r5 + r6 + r26. |
| crc8_19 = | r1 + r2 + r3 + r5 + r6 + r7 + r27. |
| crc8_20 = | r3 + r4 + r6 + r7 + r28. |
| crc8_21 = | r2 + r4 + r5 + r7 + r29. |
| crc8_22 = | r2 + r3 + r5 + r6 + r30. |
| crc8_23 = | r3 + r4 + r6 + r7 + r31. |
| crc8_24 = | b0 + r0 + r2 + r4 + r5 + r7. |
| crc8_25 = | b1 + r0 + r1 + r2 + r3 + r5 + r6. |
| crc8_26 = | b2 + r0 + r1 + r2 + r3 + r4 + r6 + r7. |
| crc8_27 = | b3 + r1 + r3 + r4 + r5 + r7. |
| crc8_28 = | b4 + r0 + r4 + r5 + r6. |
| crc8_29 = | b5 + r0 + r1 + r5 + r6 + r7. |
| crc8_30 = | b6 + r0 + r1 + r6 + r7. |
| crc8_31 = | b7 + r1 + r7. |

16-bit CRC Equations

| | |
|---|---|
| Number of 2-input exclusive-or gates: | 215 |
| Maximum number of terms: | 11 |
| Maximum Levels: | 4 |

| | |
|---|---|
| crc16_0 = | r0 + r4 + r6 + r7 + r10 + r16. |
| crc16_1 = | r1 + r5 + r7 + r8 + r11 + r17. |
| crc16_2 = | r2 + r6 + r8 + r9 + r12 + r18. |
| crc16_3 = | r3 + r7 + r9 + r10 + r13 + r19. |
| crc16_4 = | r4 + r8 + r10 + r11 + r14 + r20. |
| crc16_5 = | r5 + r9 + r11 + r12 + r15 + r21. |
| crc16_6 = | r0 + r4 + r7 + r12 + r13 + r22. |
| crc16_7 = | r1 + r5 + r8 + r13 + r14 + r23. |
| crc16_8 = | r0 + r2 + r6 + r9 + r14 + r15 + r24. |
| crc16_9 = | r1 + r3 + r4 + r6 + r15 + r25. |
| crc16_10 = | r2 + r5 + r6 + r10 + r26. |
| crc16_11 = | r3 + r6 + r7 + r11 + r27. |
| crc16_12 = | r0 + r4 + r7 + r8 + r12 + r28. |
| crc16_13 = | r0 + r1 + r5 + r8 + r9 + r13 + r29. |
| crc16_14 = | r1 + r2 + r6 + r9 + r10 + r14 + r30. |
| crc16_15 = | r2 + r3 + r7 + r10 + r11 + r15 + r31. |
| crc16_16 = | b0 + r0 + r3 + r6 + r7 + r8 + r10 + r11 + r12. |
| crc16_17 = | b1 + r0 + r1 + r4 + r7 + r8 + r9 + r11 + r12 + r13. |
| crc16_18 = | b2 + r1 + r2 + r5 + r8 + r9 + r10 + r12 + r13 + r14. |
| crc16_19 = | b3 + r0 + r2 + r3 + r6 + r9 + r10 + r11 + r13 + r14 + r15. |
| crc16_20 = | b4 + r0 + r1 + r3 + r6 + r11 + r12 + r14 + r15. |
| crc16_21 = | b5 + r1 + r2 + r6 + r10 + r12 + r13 + r15. |
| crc16_22 = | b6 + r2 + r3 + r4 + r6 + r10 + r11 + r13 + r14. |
| crc16_23 = | b7 + r3 + r4 + r5 + r7 + r11 + r12 + r14 + r15. |
| crc16_24 = | b8 + r0 + r5 + r7 + r8 + r10 + r12 + r13 + r15. |
| crc16_25 = | b9 + r1 + r4 + r7 + r8 + r9 + r10 + r11 + r13 + r14. |
| crc16_26 = | b10 + r2 + r5 + r8 + r9 + r10 + r11 + r12 + r14 + r15. |
| crc16_27 = | b11 + r0 + r3 + r4 + r7 + r9 + r11 + r12 + r13 + r15. |
| crc16_28 = | b12 + r0 + r1 + r5 + r6 + r7 + r8 + r12 + r13 + r14. |
| crc16_29 = | b13 + r1 + r2 + r6 + r7 + r8 + r9 + r13 + r14 + r15. |
| crc16_30 = | b14 + r2 + r3 + r4 + r6 + r8 + r9 + r14 + r15. |
| crc16_31 = | b15 + r3 + r5 + r6 + r9 + r15. |

24-bit CRC Equations

| | |
|---|---|
| Number of 2-input exclusive-or gates: | 319 |
| Maximum number of terms: | 14 |
| Maximum Levels: | 4 |

| | |
|---|---|
| crc24_0 = | r0 + r8 + r12 + r14 + r15 + r18 + r24. |
| crc24_1 = | r0 + r1 + r9 + r13 + r15 + r16 + r19 + r25. |
| crc24_2 = | r0 + r1 + r2 + r10 + r14 + r16 + r17 + r20 + r26. |
| crc24_3 = | r1 + r2 + r3 + r11 + r15 + r17 + r18 + r21 + r27. |
| crc24_4 = | r0 + r2 + r3 + r4 + r12 + r16 + r18 + r19 + r22 + r28. |
| crc24_5 = | r0 + r1 + r3 + r4 + r5 + r13 + r17 + r19 + r20 + r23 + r29. |
| crc24_6 = | r1 + r2 + r4 + r5 + r6 + r8 + r12 + r15 + r20 + r21 + r30. |
| crc24_7 = | r2 + r3 + r5 + r6 + r7 + r9 + r13 + r16 + r21 + r22 + r31. |
| crc24_8 = | b0 + r3 + r4 + r6 + r7 + r8 + r10 + r14 + r17 + r22 + r23. |
| crc24_9 = | b1 + r0 + r4 + r5 + r7 + r9 + r11 + r12 + r14 + r23. |
| crc24_10 = | b2 + r1 + r5 + r6 + r10 + r13 + r14 + r18. |
| crc24_11 = | b3 + r0 + r2 + r6 + r7 + r11 + r14 + r15 + r19. |
| crc24_12 = | b4 + r1 + r3 + r7 + r8 + r12 + r15 + r16 + r20. |
| crc24_13 = | b5 + r0 + r2 + r4 + r8 + r9 + r13 + r16 + r17 + r21. |
| crc24_14 = | b6 + r0 + r1 + r3 + r5 + r9 + r10 + r14 + r17 + r18 + r22. |
| crc24_15 = | b7 + r1 + r2 + r4 + r6 + r10 + r11 + r15 + r18 + r19 + r23 |
| crc24_16 = | b8 + r2 + r3 + r5 + r7 + r8 + r11 + r14 + r15 + r16 + r18 + r19 + r20. |
| crc24_17 = | b9 + r0 + r3 + r4 + r6 + r8 + r9 + r12 + r15 + r16 + r17 + r19 + r20 + |
| | r21. |
| crc24_18 = | b10 + r1 + r4 + r5 + r7 + r9 + r10 + r13 + r16 + r17 + r18 + r20 + r21 + |
| | r22. |
| crc24_19 = | b11 + r2 + r5 + r6 + r8 + r10 + r11 + r14 + r17 + r18 + r19 + r21 + r22 + |
| | r23. |
| crc24_20 = | b12 + r3 + r6 + r7 + r8 + r9 + r11 + r14 + r19 + r20 + r22 + r23. |
| crc24_21 = | b13 + r4 + r7 + r9 + r10 + r14 + r18 + r20 + r21 + r23. |
| crc24_22 = | b14 + r0 + r5 + r10 + r11 + r12 + r14 + r18 + r19 + r21 + r22. |
| crc24_23 = | b15 + r0 + r1 + r6 + r11 + r12 + r13 + r15 + r19 + r20 + r22 + r23. |
| crc24_24 = | b16 + r0 + r1 + r2 + r7 + r8 + r13 + r15 + r16 + r18 + r20 + r21 + r23. |
| crc24_25 = | b17 + r1 + r2 + r3 + r9 + r12 + r15 + r16 + r17 + r18 + r19 + r21 + r22. |
| crc24_26 = | b18 + r2 + r3 + r4 + r10 + r13 + r16 + r17 + r18 + r19 + r20 + r22 + r23. |
| crc24_27 = | b19 + r3 + r4 + r5 + r8 + r11 + r12 + r15 + r17 + r19 + r20 + r21 + r23. |
| crc24_28 = | b20 + r4 + r5 + r6 + r8 + r9 + r13 + r14 + r15 + r16 + r20 + r21 + r22. |
| crc24_29 = | b21 + r5 + r6 + r7 + r9 + r10 + r14 + r15 + r16 + r17 + r21 + r22 + r23. |
| crc24_30 = | b22 + r6 + r7 + r10 + r11 + r12 + r14 + r16 + r17 + r22 + 23. |
| crc24_31 = | b23 + r7 + r11 + r13 + r14 + r17 + r23. |

32-bit CRC Equations

| | |
|---|---|
| Number of 2-input exclusive-or gates: | 452 |
| Maximum number of terms: | 18 |
| Maximum Levels: | 5 |

| | |
|---|---|
| crc32_0 = | b0 + r0 + r1 + r2 + r3 + r4 + r6 + r7 + r8 + r16 + r20 + r22 + r23 + r26. |
| crc32_1 = | b1 + r1 + r2 + r3 + r4 + r5 + r7 + r8 + r9 + r17 + r21 + r23 + r24 + r27. |
| crc32_2 = | b2 + r0 + r2 + r3 + r4 + r5 + r6 + r8 + r9 + r10 + r18 + r22 + r24 + r25 + |
| | r28. |
| crc32_3 = | b3 + r1 + r3 + r4 + r5 + r6 + r7 + r9 + r10 + r11 + r19 + r23 + r25 + r26 + |
| | r29. |
| crc32_4 = | b4 + r2 + r4 + r5 + r6 + r7 + r8 + r10 + r11 + r12 + r20 + r24 + r26 + r27 + |
| | r30. |
| crc32_5 = | b5 + r0 + r3 + r5 + r6 + r7 + r8 + r9 + r11 + r12 + r13 + r21 + r25 + r27 + |
| | r28 + r31. |
| crc32_6 = | b6 + r0 + r2 + r3 + r9 + r10 + r12 + r13 + r14 + r16 + r20 + r23 + r28 + |
| | r29. |
| crc32_7 = | b7 + r1 + r3 + r4 + r10 + r11 + r13 + r14 + r15 + r17 + r21 + r24 + r29 + |
| | r30. |
| crc32_8 = | b8 + r0 + r2 + r4 + r5 + r11 + r12 + r14 + r15 + r16 + r18 + r22 + r25 + |
| | r30 + r31. |
| crc32_9 = | b9 + r0 + r2 + r4 + r5 + r7 + r8 + r12 + r13 + r15 + r17 + r19 + r20 + r22 + |
| | r31. |
| crc32_10 = | b10 + r0 + r2 + r4 + r5 + r7 + r9 + r13 + r14 + r18 + r21 + r22 + r26. |
| crc32_11 = | b11 + r1 + r3 + r5 + r6 + r8 + r10 + r14 + r15 + r19 + r22 + r23 + r27. |
| crc32_12 = | b12 + r2 + r4 + r6 + r7 + r9 + r11 + r15 + r16 + r20 + r23 + r24 + r28. |
| crc32_13 = | b13 + r0 + r3 + r5 + r7 + r8 + r10 + r12 + r16 + r17 + r21 + r24 + r25 + |
| | r29. |
| crc32_14 = | b14 + r0 + r1 + r4 + r6 + r8 + r9 + r11 + r13 + r17 + r18 + r22 + r25 + |
| | r26 + r30. |
| crc32_15 = | b15 + r1 + r2 + r5 + r7 + r9 + r10 + r12 + r14 + r18 + r19 + r23 + r26 + |
| | r27 + r31. |
| crc32_16 = | b16 + r1 + r4 + r7 + r10 + r11 + r13 + r15 + r16 + r19 + r22 + r23 + r24 + |
| | r26 + r27 + r28. |
| crc32_17 = | b17 + r2 + r5 + r8 + r11 + r12 + r14 + r16 + r17 + r20 + r23 + r24 + r25 + |
| | r27 + r28 + r29. |
| crc32_18 = | b18 + r0 + r3 + r6 + r9 + r12 + r13 + r15 + r17 + r18 + r21 + r24 + r25 + |
| | r26 + r28 + r29 + r30. |
| crc32_19 = | b19 + r0 + r1 + r4 + r7 + r10 + r13 + r14 + r16 + r18 + r19 + r22 + r25 + |
| | r26 + r27 + r29 + r30 + r31. |
| crc32_20 = | b20 + r0 + r3 + r4 + r5 + r6 + r7 + r11 + r14 + r15 + r16 + r17 + r19 + |
| | r22 + r27 + r28 + r30 + r31. |
| crc32_21 = | b21 + r0 + r2 + r3 + r5 + r12 + r15 + r17 + r18 + r22 + r26 + r28 + r29 + |
| | r31. |
| crc32_22 = | b22 + r2 + r7 + r8 + r13 + r18 + r19 + r20 + r22 + r26 + r27 + r29 + r30. |
| crc32_23 = | b23 + r0 + r3 + r8 + r9 + r14 + r19 + r20 + r21 + r23 + r27 + r28 + r30 + |
| | r31. |
| crc32_24 = | b24 + r2 + r3 + r6 + r7 + r8 + r9 + r10 + r15 + r16 + r21 + r23 + r24 + |
| | r26 + r28 + r29 + r31. |
| crc32_25 = | b25 + r1 + r2 + r6 + r9 + r10 + r11 + r17 + r20 + r23 + r24 + r25 + r26 + |
| | r27 + r29 + r30. |
| crc32_26 = | b26 + r2 + r3 + r7 + r10 + r11 + r12 + r18 + r21 + r24 + r25 + r26 + r27 + |
| | r28 + r30 + r31. |
| crc32_27 = | b27 + r0 + r1 + r2 + r6 + r7 + r11 + r12 + r13 + r16 + r19 + r20 + r23 + |
| | r25 + r27 + r28 + r29 + r31. |
| crc32_28 = | b28 + r0 + r4 + r6 + r12 + r13 + r14 + r16 + r17 + r21 + r22 + r23 + r24 + |
| | r28 + r29 + r30. |
| crc32_29 = | b29 + r0 + r1 + r5 + r7 + r13 + r14 + r15 + r17 + r18 + r22 + r23 + r24 + |
| | r25 + r29 + r30 + r31. |
| crc32_30 = | b30 + r3 + r4 + r7 + r14 + r15 + r18 + r19 + r20 + r22 + r24 + r25 + r30 + |
| | r31. |
| crc32_31 = | b31 + r0 + r1 + r2 + r3 + r5 + r6 + r7 + r15 + r19 + r21 + r22 + r25 + |
| | r31. |

40-bit CRC Equations

| | |
|---|---|
| Number of 2-input exclusive-or gates: | 557 |
| Maximum number of terms: | 23 |
| Maximum Levels: | 5 |

| | |
|---|---|
| crc40_0 = | b2 + b8 + r3 + r6 + r8 + r9 + r10 + r11 + r12 + r14 + r15 + r16 + r24 + |
| | r28 + r30 + r31. |
| crc40_1 = | b0 + b3 + b9 + r4 + r7 + r9 + r10 + r11 + r12 + r13 + r15 + r16 + r17 + |
| | r25 + r29 + r31. |
| crc40_2 = | b0 + b1 + b4 + b10 + r5 + r8 + r10 + r11 + r12 + r13 + r14 + r16 + r17 + |
| | r18 + r26 + r30. |
| crc40_3 = | b1 + b2 + b5 + b11 + r6 + r9 + r11 + r12 + r13 + r14 + r15 + r17 + r18 + |
| | r19 + r27 + r31. |
| crc40_4 = | b0 + b2 + b3 + b6 + b12 + r0 + r7 + r10 + r12 + r13 + r14 + r15 + r16 + |
| | r18 + r19 + r20 + r28. |
| crc40_5 = | b1 + b3 + b4 + b7 + b13 + r0 + r1 + r8 + r11 + r13 + r14 + r15 + r16 + |
| | r17 + r19 + r20 + r21 + r29. |
| crc40_6 = | b4 + b5 + b14 + r1 + r2 + r3 + r6 + r8 + r10 + r11 + r17 + r18 + r20 + |
| | r21 + r22 + r24 + r28 + r31. |
| crc40_7 = | b0 + b5 + b6 + b15 + r0 + r2 + r3 + r4 + r7 + r9 + r11 + r12 + r18 + r19 + |
| | r21 + r22 + r23 + r25 + r29. |
| crc40_8 = | b1 + b6 + b7 + b16 + r0 + r1 + r3 + r4 + r5 + r8 + r10 + r12 + r13 + r19 + |
| | r20 + r22 + r23 + r24 + r26 + r30. |
| crc40_9 = | b7 + b17 + r1 + r2 + r3 + r4 + r5 + r8 + r10 + r12 + r13 + r15 + r16 + |
| | r20 + r21 + r23 + r25 + r27 + r28 + r30. |
| crc40_10 = | b2 + b18 + r2 + r4 + r5 + r8 + r10 + r12 + r13 + r15 + r17 + r21 + r22 + |
| | r26 + r29 + r30. |
| crc40_11 = | b3 + b19 + r0 r3 + r5 + r6 + r9 + r11 + r13 + r14 + r16 + r18 + r22 + |
| | r23 + r27 + r30 + r31. |
| crc40_12 = | b0 + b4 + b20 + r1 + r4 + r6 + r7 + r10 + r12 + r14 + r15 + r17 + r19 + |
| | r23 + r24 + r28 + r31. |
| crc40_13 = | b0 + b1 + b5 + b21 + r0 + r2 + r5 + r7 + r8 + r11 + r13 + r15 + r16 + r18 + |
| | r20 + r24 + r25 + r29. |
| crc40_14 = | b1 + b2 + b6 + b22 + r1 + r3 + r6 + r8 + r9 + r12 + r14 + r16 + r17 + r19 + |
| | r21 + r25 + r26 + r30. |
| crc40_15 = | b2 + b3 + b7 + b23 + r2 + r4 + r7 + r9 + r10 + r13 + r15 + r17 + r18 + |
| | r20 + r22 + r26 + r27 + r31. |
| crc40_16 = | b0 + b2 + b3 + b4 + b24 + r5 + r6 + r9 + r12 + r15 + r18 + r19 + r21 + |
| | r23 + r24 + r27 + r30 + r31. |
| crc40_17 = | b0 + b1 + b3 + b4 + b5 + b25 + r6 + r7 + r10 + r13 + r16 + r19 + r20 + |
| | r22 + r24 + r25 + r28 + r31. |
| crc40_18 = | b0 + b1 + b2 + b4 + b5 + b6 + b26 + r7 + r8 + r11 + r14 + r17 + r20 + |
| | r21 + r23 + r25 + r26 + r29. |
| crc40_19 = | b1 + b2 + b3 + b5 + b6 + b7 + b27 + r8 + r9 + r12 + r15 + r18 + r21 + |
| | r22 + r24 + r26 + r27 + r30. |
| crc40_20 = | b3 + b4 + b6 + b7 + b28 + r3 + r6 + r8 + r11 + r12 + r13 + r14 + r15 + |
| | r19 + r22 + r23 + r24 + r25 + r27 + r30. |
| crc40_21 = | b2 + b4 + b5 + b27 + b29 + r0 + r3 + r4 + r6 + r7 + r8 + r10 + r11 + r13 + |
| | r20 + r23 + r25 + r26 + r30. |
| crc40_22 = | b2 + b3 + b5 + b6 + b30 + r0 + r1 + r3 + r4 + r5 + r6 + r7 + r10 + r15 + |
| | r16 + r21 + r26 + r27 + r28 + r30. |
| crc40_23 = | b3 + b4 + b6 + b7 + b31 + r1 + r2 + r4 + r5 + r6 + r7 + r8 + r11 + r16 + |
| | r17 + r22 + r27 + r28 + r29 + r31. |
| crc40_24 = | b0 + b2 + b4 + b5 + b7 + b32 + r0 + r2 + r5 + r7 + r10 + r11 + r 14 + r15 + |
| | r16 + r17 + r18 + r23 + r24 + r29 + r31. |
| crc40_25 = | b0 + b1 + b2 + b3 + b5 + b6 + b33 + r1 + r9 + r10 + r14 + r17 + r18 + |
| | r19 + r25 + r28 + r31. |
| crc40_26 = | b0 + b1 + b2 + b3 + b4 + b6 + b7 + b34 + r0 + r2 + r10 + r11 + r15 + |
| | r18 + r19 + r20 + r26 + r29. |
| crc40_27 = | b1 + b3 + b4 + b5 + b7 + b35 + r0 + r1 + r6 + r8 + r9 + r10 + r14 + r15 + |
| | r19 + r20 + r21 + r24 + r27 + r28 + r31. |
| crc40_28 = | b0 + b4 + b5 + b6 + b36 + r0 + r1 + r2 + r3 + r6 + r7 + r8 + r12 + r14 + |
| | r20 + r21 + r22 + r24 + r25 + r29 + r30 + r31. |
| crc40_29 = | b0 + b1 + b5 + b6 + b7 + b37 + r0 + r1 + r2 + r3 + r4 + r7 + r8 + r9 + |
| | r13 + r15 + r21 + r22 + r23 + r25 + r26 + r30 + r31. |
| crc40_30 = | b0 + b1 + b6 + b7 + b38 + r1 + r2 + r4 + r5 + r6 + r11 + r12 + r15 + r22 + |
| | r23 + r26 + r27 + r28 + r30. |
| crc40_31 = | b1 + b7 + b39 + r2 + r5 + r7 + r8 + r9 + r10 + r11 + r13 + r14 + r15 + |
| | r23 + r27 + r29 + r30. |

48-bit CRC Equations

| | |
|---|---|
| Number of 2-input exclusive-or gates: | 669 |
| Maximum number of terms: | 27 |
| Maximum Levels: | 5 |

| | |
|---|---|
| crc48_0 = | b0 + b4 + b6 + b7 + b10 + b16 + r0 + r1 + r3 + r4 + r11 + r14 + r16 + |
| | r17 + r18 + r19 + r20 + r22 + r23 + r24. |
| crc48_1 = | b1 + b5 + b7 + b8 + b11 + b17 + r1 + r2 + r4 + r5 + r12 + r15 + r17 + |
| | r18 + r19 + r20 + r21 + r23 + r24 + r25. |
| crc48_2 = | b2 + b6 + b8 + b9 + b12 + b18 + r0 + r2 + r3 + r5 + r6 + r13 + r16 + r18 + |
| | r19 + r20 + r21 + r22 + r24 + r25 + r26. |
| crc48_3 = | b3 + b7 + b9 + b10 + b13 + b19 + r1 + r3 + r4 + r6 + r7 + r14 + r17 + |
| | r19 + r20 + r21 + r22 + r23 + r25 + r26 + r27. |
| crc48_4 = | b4 + b8 + b10 + b11 + b14 + b20 + r2 + r4 + r5 + r7 + r8 + r15 + r18 + |
| | r20 + r21 + r22 + r23 + r24 + r26 + r27 + r28. |
| crc48_5 = | b5 + b9 + b11 + b12 + b15 + b21 + r0 + r3 + r5 + r6 + r8 + r9 + r16 + |
| | r19 + r21 + r22 + r23 + r24 + r25 + r27 + r28 + r29. |
| crc48_6 = | b0 + b4 + b7 + b12 + b13 + b22 + r3 + r6 + r7 + r9 + r10 + r11 + r14 + |
| | r16 + r18 + r19 + r25 + r26 + r28 + r29 + r30. |
| crc48_7 = | b1 + b5 + b8 + b13 + b14 + b23 + r0 + r4 + r7 + r8 + r10 + r11 + r12 + |
| | r15 + r17 + r19 + r20 + r26 + r27 + r29 + r30 + r31. |
| crc48_8 = | b0 + b2 + b6 + b9 + b14 + b15 + b24 + r0 + r1 + r5 + r8 + r9 + r11 + r12 + |
| | r13 + r16 + r18 + r20 + r21 + r27 + r28 + r30 + r31. |
| crc48_9 = | b1 + b3 + b4 + b15 + b25 + r0 + r2 + r3 + r4 + r6 + r9 + r10 + r11 + |
| | r12 + r13 + r16 + r18 + r20 + r21 + r23 + r24 + r28 + r29 + r31. |
| crc48_10 = | b2 + b5 + b6 + b10 + b26 + r5 + r7 + r10 + r12 + r13 + r16 + r18 + r20 + |
| | r21 + r23 + r25 + r29 + r30. |
| crc48_11 = | b3 + b6 + b7 + b11 + b27 + r6 + r8 + r11 + r13 + r14 + r17 + r19 + r21 + |
| | r22 + r24 + r26 + r30 + r31. |
| crc48_12 = | b0 + b4 + b7 + b8 + b12 + b28 + r0 + r7 + r9 + r12 + r14 + r15 + r18 + |
| | r20 + r22 + r23 + r25 + r27 + r31. |
| crc48_13 = | b0 + b1 + b5 + b8 + b9 + b13 + b29 + r1 + r8 + r10 + r13 + r15 + r16 + |
| | r19 + r21 + r23 + r24 + r26 + r28. |
| crc48_14 = | b1 + b2 + b6 + b9 + b10 + b14 + b30 + r0 + r2 + r9 + r11 + r14 + r16 + |
| | r17 + r20 + r22 + r24 + r25 + r27 + r29. |
| crc48_15 = | b2 + b3 + b7 + b10 + b11 + b15 + b31 + r0 + r1 + r3 + r10 + r12 + r15 + |
| | r17 + r18 + r21 + r23 + r25 + r26 + r28 + r30. |
| crc48_16 = | b0 + b3 + b6 + b7 + b8 + b10 + b11 + b12 + b32 + r2 + r3 + r13 + r14 + |
| | r17 + r20 + r23 + r26 + r27 + r29 + r31. |
| crc48_17 = | b0 + b1 + b4 + b7 + b8 + b9 + b11 + b12 + b13 + b33 + r3 + r4 + r14 + |
| | r15 + r18 + r21 + r24 + r27 + r28 + r30. |
| crc48_18 = | b1 + b2 + b5 + b8 + b9 + b10 + b12 + b13 + b14 + b34 + r0 + r4 + r5 + |
| | r15 + r16 + r19 + r22 + r25 + r28 + r29 + r31. |
| crc48_19 = | b0 + b2 + b3 + b6 + b9 + b10 + b11 + b13 + b14 + b15 + b35 + r0 + r1 + |
| | r5 + r6 + r16 + r17 + r20 + r23 + r26 + r29 + r30. |
| crc48_20 = | b0 + b1 + b3 + b6 + b11 + b12 + b14 + b15 + b36 + r0 + r2 + r3 + r4 + |
| | r6 + r7 + r11 + r14 + r16 + r19 + r20 + r21 + r22 + r23 + r27 + r30 + r31. |
| crc48_21 = | b1 + b2 + b6 + b10 + b12 + b13 + b15 + b37 + r5 + r7 + r8 + r11 + r12 + |
| | r14 + r15 + r16 + r18 + r19 + r21 + r28 + r31. |
| crc48_22 = | b2 + b3 + b4 + b6 + b10 + b11 + b13 + b14 + b38 + r0 + r1 + r3 + r4 + |
| | r6 + r8 + r9 + r11 + r12 + r13 + r14 + r15 + r18 + r23 + r24 + r29. |
| crc48_23 = | b3 + b4 + b5 + b7 + b11 + b12 + b14 + b15 + b39 + r1 + r2 + r4 + r5 + |
| | r7 + r9 + r10 + r12 + r13 + r14 + r15 + r16 + r19 + r24 + r25 + r30. |
| crc48_24 = | b0 + b5 + b7 + b8 + b10 + b12 + b13 + b15 + b40 + r0 + r1 + r2 + r4 + |
| | r5 + r6 + r8 + r10 + r13 + r15 + r18 + r19 + r22 + r23 + r24 + r25 + r26 + r31. |
| crc48_14 = | b1 + b2 + b6 + b9 + b10 + b14 + b30 + r0 + r2 + r9 + r11 + r14 + r16 + |
| | r17 + r20 + r22 + r24 + r25 + r27 + r29. |
| crc48_15 = | b2 + b3 + b7 + b10 + b11 + b15 + b31 + r0 + r1 + r3 + r10 + r12 + r15 + |
| | r17 + r18 + r21 + r23 + r25 + r26 + r28 + r30. |
| crc48_16 = | b0 + b3 + b6 + b7 + b8 + b10 + b11 + b12 + b32 + r2 + r3 + r13 + r14 + |
| | r17 + r20 + r23 + r26 + r27 + r29 + r31. |
| crc48_17 = | b0 + b1 + b4 + b7 + b8 + b9 + b11 + b12 + b13 + b33 + r3 + r4 + r14 + |
| | r15 + r18 + r21 + r24 + r27 + r28 + r30. |
| crc48_18 = | b1 + b2 + b5 + b8 + b9 + b10 + b12 + b13 + b14 + b34 + r0 + r4 + r5 + |
| | r15 + r16 + r19 + r22 + r25 + r28 + r29 + r31. |
| crc48_19 = | b0 + b2 + b3 + b6 + b9 + b10 + b11 + b13 + b14 + b15 + b35 + r0 + r1 + |
| | r5 + r6 + r16 + r17 + r20 + r23 + r26 + r29 + r30. |
| crc48_20 = | b0 + b1 + b3 + b6 + b11 + b12 + b14 + b15 + b36 + r0 + r2 + r3 + r4 + |
| | r6 + r7 + r11 + r14 + r16 + r19 + r20 + r21 + r22 + r23 + r27 + r30 + r31. |
| crc48_21 = | b1 + b2 + b6 + b10 + b12 + b13 + b15 + b37 + r5 + r7 + r8 + r11 + r12 + |
| | r14 + r15 + r16 + r18 + r19 + r21 + r28 + r31. |
| crc48_22 = | b2 + b3 + b4 + b6 + b10 + b11 + b13 + b14 + b38 + r0 + r1 + r3 + r4 + |
| | r6 + r8 + r9 + r11 + r12 + r13 + r14 + r15 + r18 + r23 + r24 + r29. |
| crc48_23 = | b3 + b4 + b5 + b7 + b11 + b12 + b14 + b15 + b39 + r1 + r2 + r4 + r5 + |
| | r7 + r9 + r10 + r12 + r13 + r14 + r15 + r16 + r19 + r24 + r25 + r30. |
| crc48_24 = | b0 + b5 + b7 + b8 + b10 + b12 + b13 + b15 + b40 + r0 + r1 + r2 + r4 + |
| | r5 + r6 + r8 + r10 + r13 + r15 + r18 + r19 + r22 + r23 + r24 + r25 + r26 + r31. |
| crc48_25 = | b1 + b4 + b7 + b8 + b9 + b10 + b11 + b13 + b14 + b41 + r0 + r2 + r4 + |
| | r5 + r6 + r7 + r9 + r17 + r18 + r22 + r25 + r26 + r27. |
| crc48_26 = | b2 + b5 + b8 + b9 + b10 + b11 + b12 + b14 + b15 + b42 + r1 + r3 + r5 + |
| | r6 + r7 + r8 + r10 + r18 + r19 + r23 + r26 + t27 + r28. |
| crc48_27 = | b0 + b3 + b4 + b7 + b9 + b11 + b12 + b13 + b15 + b43 + r0 + r1 + r2 + |
| | r3 + r6 + r7 + r8 + r9 + r14 + r16 + r17 + r18 + r22 + r23 + r27 + r28 + r29. |
| crc48_28 = | b0 + b1 + b5 + b6 + b7 + b8 + b12 + b13 + b14 + b44 + r2 + r7 + r8 + r9 + |
| | r10 + r11 + r14 + r15 + r16 + r20 + r22 + r28 + r29 + r30. |
| crc48_29 = | b1 + b2 + b6 + b7 + b8 + b9 + b13 + b14 + b15 + b45 + r3 + r8 + r9 + |
| | r10 + r11 + r12 + r15 + r16 + r17 + r21 + r23 + r29 + r30 + r31. |
| crc48_30 = | b2 + b3 + b4 + b6 + b8 + b9 + b14 + b15 + b46 + r0 + r1 + r3 + r9 + r10 + |
| | r12 + r13 + r14 + r19 + r20 + r23 + r30 + r31. |
| crc48_31 = | b3 + b5 + b6 + b9 + b15 + b47 + r0 + r2 + r3 + r10 + r13 + r15 + r16 + |
| | r17 + r18 + r19 + r21 + r22 + r23 + r31. |

56-bit CRC Equations

| | |
|---|---|
| Number of 2-input exclusive-or gates: | 807 |
| Maximum number of terms: | 31 |
| Maximum Levels: | 5 |

| | |
|---|---|
| crc56_0 = | b0 + b8 + b12 + b14 + b15 + b18 + b24 + r1 + r2 + r3 + r6 + r8 + r9 + |
| | r11 + r12 + r19 + r22 + r24 + r25 + r26 + r27 + r28 + r30 + r31. |
| crc56_1 = | b0 + b1 + b9 + b13 + b15 + b16 + b19 + b25 + r2 + r3 + r4 + r7 + r9 + |
| | r10 + r12 + r13 + r20 + r23 + r25 + r26 + r27 + r28 + r29 + r31. |
| crc56_2 = | b0 + b1 + b2 + b10 + b14 + b16 + b17 + b20 + b26 + r0 + r3 + r4 + r5 + |
| | r8 + r10 + r11 + r13 + r14 + r21 + r24 + r26 + r27 + r28 + r29 + r30. |
| crc56_3 = | b1 + b2 + b3 + b11 + b15 + b17 + b18 + b21 + b27 + r1 + r4 + r5 + r6 + |
| | r9 + r11 + r12 + r14 + r15 + r22 + r25 + r27 + r28 + r29 + r30 + r31. |
| crc56_4 = | b0 + b2 + b3 + b4 + b12 + b16 + b18 + b19 + b22 + b28 + r0 + r2 + r5 + |
| | r6 + r7 + r10 + r12 + r13 + r15 + r16 + r23 + r26 + r28 + r29 + r30 + r31. |
| crc56_5 = | b0 + b1 + b3 + b4 + b5 + b13 + b17 + b19 + b20 + b23 + b29 + r0 + r1 + |
| | r3 + r6 + r7 + r8 + r11 + r13 + r14 + r16 + r17 + r24 + r27 + r29 + r30 + r31. |
| crc56_6 = | b1 + b2 + b4 + b5 + b6 + b8 + b12 + b15 + b20 + b21 + b30 + r3 + r4 + |
| | r6 + r7 + r11 + r14 + r15 + r17 + r18 + r19 + r22 + r24 + r26 + r27. |
| crc56_7 = | b2 + b3 + b5 + b6 + b7 + b9 + b13 + b16 + b21 + b22 + b31 + r0 + r4 + |
| | r5 + r7 + r8 + r12 + r15 + r16 + r18 + r19 + r20 + r23 + r25 + r27 + r28. |
| crc56_8 = | b3 + b4 + b6 + b7 + b8 + b10 + b14 + b17 + b22 + b23 + b32 + r0 + r1 + |
| | r5 + r6 + r8 + r9 + r13 + r16 + r17 + r19 + r20 + r21 + r24 + r26 + r28 + 29. |
| crc56_9 = | b0 + b4 + b5 + b7 + b9 + b11 + b12 + b14 + b23 + b33 + r0 + r3 + r7 + |
| | r8 + r10 + r11 + r12 + r14 + r17 + r18 + r19 + r20 + r21 + r24 + r26 + r28 + r29 + r31. |
| crc56_10 = | b1 + b5 + b6 + b10 + b13 + b14 + b18 + b34 + r2 + r3 + r4 + r6 + r13 + |
| | r15 + r18 + r20 + r21 + r24 + r26 + r28 + r29 + r31. |
| crc56_11 = | b0 + b2 + b6 + b7 + b11 + b14 + b15 + b19 + b35 + r0 + r3 + r5 + |
| | r7 + r14 + r16 + r19 + r21 + r22 + r25 + r27 + r29 + r30. |
| crc56_12 = | b1 + b3 + b7 + b8 + b12 + b15 + b16 + b20 + b36 + r1 + r4 + r5 + r6 + |
| | r8 + r15 + r17 + r20 + r22 + r23 + r26 + r28 + r30 + r31. |
| crc56_13 = | b0 + b2 + b4 + b8 + b9 + b13 + b16 + b17 + b21 + b37 + r2 + r5 + r6 + |
| | r7 + r9 + r16 + r18 + r21 + r23 + r24 + r27 + r29 + r31. |
| crc56_14 = | b0 + b1 + b3 + b5 + b9 + b10 + b14 + b17 + b18 + b22 + b38 + r3 + r6 + |
| | r7 + r8 + r10 + r17 + r19 + r22 + r24 + r25 + r28 + r30. |
| crc56_15 = | b1 + b2 + b4 + b6 + b10 + b11 + b15 + b18 + b19 + b23 + b39 + r4 + r7 + |
| | r8 + r9 + r11 + r18 + r20 + r23 + r25 + r26 + r29 + r31. |
| crc56_16 = | b2 + b3 + b5 + b7 + b8 + b11 + b14 + b15 + b16 + b18 + b19 + b20 + |
| | b40 + r0 + r1 + r2 + r3 + r5 + r6 + r10 + r11 + r21 + r22 + r25 + r28 + r31. |
| crc56_17 = | b0 + b3 + b4 + b6 + b8 + b9 + b12 + b15 + b16 + b17 + b19 + b20 + b21 + |
| | b41 + r0 + r1 + r2 + r3 + r4 + r6 + r7 + r11 + r12 + r22 + r23 + r26 + r29. |
| crc56_18 = | b1 + b4 + b5 + b7 + b9 + b10 + b13 + b16 + b17 + b18 + b20 + b21 + |
| | b22 + b42 + r0 + r1 + r2 + r3 + r4 + r5 + r7 + r8 + r12 + r13 + r23 + r24 + r27 + r30. |
| crc56_19 = | b2 + b5 + b6 + b8 + b10 + b11 + b14 + b17 + b18 + b19 + b21 + b22 + |
| | b23 + b43 + r1 + r2 + r3 + r4 + r5 + r6 + r8 + r9 + r13 + r14 + r24 + r25 + r28 + r31. |
| crc56_20 = | b3 + b6 + b7 + b8 + b9 + b11 + b14 + b19 + b20 + b22 + b23 + b44 + r0 + |
| | r1 + r4 + r5 + r7 + r8 + r10 + r11 + r12 + r14 + r15 + r19 + r22 + r24 + r27 + r28 + |
| | r29 + r30 + r31. |
| crc56_21 = | b4 + b7 + b9 + b10 + b14 + b18 + b20 + b21 + b23 + b45 + r0 + r3 + r5 + |
| | r13 + r15 + r16 + r19 + r20 + r22 + r23 + r24 + r26 + r27 + r29. |
| crc56_22 = | b0 + b5 + b10 + b11 + b12 + b14 + b18 + b19 + b21 + b22 + b46 + r0 + |
| | r2 + r3 + r4 + r8 + r9 + r11 + r12 + r14 + r16 + r17 + r19 + r20 + r21 + r22 + r23 + r26 + |
| | r31. |
| crc56_23 = | b0 + b1 + b6 + b11 + b12 + b13 + b15 + b19 + b20 + b22 + b23 + b47 + |
| | r1 + r3 + r4 + r5 + r9 + r10 + r12 + r13 + r15 + r17 + r18 + r20 + r21 + r22 + r23 + r24 + |
| | r27. |
| crc56_24 = | b0 + b1 + b2 + b7 + b8 + b13 + b15 + b16 + b18 + b20 + b21 + b23 + |
| | b48 + r1 + r3 + r4 + r5 + r8 + r9 + r10 + r12 + r13 + r14 + r16 + r18 + r21 + r23 + r26 + |
| | r27 + r30 + r31. |
| crc56_25 = | b1 + b2 + b3 + b9 + b12 + b15 + b16 + b17 + b18 + b19 + b21 + b22 + |
| | b49 + r0 + r1 + r3 + r4 + r5 + r8 + r10 + r12 + r13 + r14 + r15 + r17 + r25 + r26 + r30. |
| crc56_26 = | b2 + b3 + b4 + b10 + b13 + b16 + b17 + b18 + b19 + b20 + b22 + b23 + |
| | b50 + r0 + r1 + r2 + r4 + r5 + r6 + r9 + r11 + r13 + r14 + r15 + r16 + r18 + r26 + r27 + |
| | r31. |
| crc56_27 = | b3 + b4 + b5 + b8 + b11 + b12 + b15 + b17 + b19 + b20 + b21 + b23 + |
| | b51 + r5 + r7 + r8 + r9 + r10 + r11 + r14 + r15 + r16 + r17 + r22 + r24 + r25 + r26 + |
| | r30 + r31. |
| crc56_28 = | b4 + b5 + b6 + b8 + b9 + b13 + b14 + b15 + b16 + b20 + b21 + b22 + |
| | b52 + r1 + r2 + r3 + r10 + r15 + r16 + r17 + r18 + r19 + r22 + r23 + r24 + r28 + r30. |
| crc56_29 = | b5 + b6 + b7 + b9 + b10 + b14 + b15 + b16 + b17 + b21 + b22 + b23 + |
| | b53 + r0 + r2 + r3 + r4 + r11 + r16 + r17 + r18 + r19 + r20 + r23 + r24 + r25 + r29 + |
| | r31. |
| crc56_30 = | b6 + b7 + b10 + b11 + b12 + b14 + b16 + b17 + b22 + b23 + b54 + r2 + |
| | r4 + r5 + r6 + r8 + r9 + r11 + r17 + r18 + r20 + r21 + r22 + r27 + r28 + r31. |
| crc56_31 = | b7 + b11 + b13 + b14 + b17 + b23 + b55 + r0 + r1 + r2 + r5 + r7 + r8 + |
| | r10 + r11 + r18 + r21 + r23 + r24 + r25 + r26 + r27 + r29 + r30 + r31. |

64-bit CRC Equations

| | |
|---|---|
| Number of 2-input exclusive-or gates: | 937 |
| Maximum number of terms: | 35 |
| Maximum Levels: | 6 |

| | |
|---|---|
| crc64_0 = | b0 + b1 + b2 + b3 + b4 + b6 + b7 + b8 + b16 + b20 + b22 + b23 + b26 + |
| | b32 + r1 + r3 + r4 + r6 + r9 + r10 + r11 + r14 + r16 + r17 + r19 + r20 + r27 + r30. |
| crc64_1 = | b1 + b2 + b3 + b4 + b5 + b7 + b8 + b9 + b17 + b21 + b23 + b24 + b27 + |
| | b33 + r0 + r2 + r4 + r5 + r7 + r10 + r11 + r12 + r15 + r17 + r18 + r20 + r21 + r28 + r31. |
| crc64_2 = | b0 + b2 + b3 + b4 + b5 + b6 + b8 + b9 + b10 + b18 + b22 + b24 + b25 + |
| | b28 + b34 + r0 + r1 + r3 + r5 + r6 + r8 + r11 + r12 + r13 + r16 + r18 + r19 + r21 + r22 + r29. |
| crc64_3 = | b1 + b3 + b4 + b5 + b6 + b7 + b9 + b10 + b11 + b19 + b23 + b25 + b26 + |
| | b29 + b35 + r0 + r1 + r2 + r4 + r6 + r7 + r9 + r12 + r13 + r14 + r17 + r19 + r20 + r22 + |
| | r23 + r30. |
| crc64_4 = | b2 + b4 + b5 + b6 + b7 + b8 + b10 + b11 + b12 + b20 + b24 + b26 + b27 + |
| | b30 + b36 + r0 + r1 + r2 + r3 + r5 + r7 + r8 + r10 + r13 + r14 + r15 + r18 + r18 + r20 + r21 + |
| | r23 + r24 + r31. |
| crc64_5 = | b0 + b3 + b5 + b6 + b7 + b8 + b9 + b11 + b12 + b13 + b21 + b25 + b27 + |
| | b28 + b31 + b37 + r1 + r2 + r3 + r4 + r6 + r8 + r9 + r11 + r14 + r15 + r16 + r19 + r21 + |
| | r22 + r24 + r25. |
| crc64_6 = | b0 + b2 + b3 + b9 + b10 + b12 + b13 + b14 + b16 + b20 + b23 + b28 + |
| | b29 + b38 + r1 + r2 + r5 + r6 + r7 + r11 + r12 + r14 + r15 + r19 + r22 + r23 + r25 + r26 + |
| | r27 + r30. |
| crc64_7 = | b1 + b3 + b4 + b10 + b11 + b13 + b14 + b15 + b17 + b21 + b24 + b29 + |
| | b30 + b39 + r0 + r2 + r3 + r6 + r7 + r8 + r12 + r13 + r15 + r16 + r20 + r23 + r24 + r26 + |
| | r27 + r28 + r31. |
| crc64_8 = | b0 + b2 + b4 + b5 + b11 + b12 + b14 + b15 + b16 + b18 + b22 + b25 + |
| | b30 + b31 + b40 + r1 + r3 + r4 + r7 + r8 + r9 + r13 + r14 + r16 + r17 + r21 + r24 + r25 + |
| | r27 + r28 + r29. |
| crc64_9 = | b0 + b2 + b4 + b5 + b7 + b8 + b12 + b13 + b15 + b17 + b19 + b20 + b22 + |
| | b31 + b41 + r1 + r2 + r3 + r5 + r6 + r8 + r11 + r15 + r16 + r18 + r19 + r20 + r22 + |
| | r25 + r26 + r27 + r28 + r29. |
| crc64_10 = | b0 + b2 + b4 + b5 + b7 + b9 + b13 + b14 + b18 + b21 + b22 + b26 + b42 + |
| | r1 + r2 + r7 + r10 + r11 + r12 + r14 + r21 + r23 + r26 + r28 + r29. |
| crc64_11 = | b1 + b3 + b5 + b6 + b8 + b10 + b14 + b15 + b19 + b22 + b23 + b27 + |
| | b43 + r2 + r3 + r8 + r11 + r12 + r13 + r15 + r22 + r24 + r27 + r29 + r30. |
| crc64_12 = | b2 + b4 + b6 + b7 + b9 + b11 + b15 + b16 + b20 + b23 + b24 + b28 + |
| | b44 + r3 + r4 + r9 + r12 + r13 + r14 + r16 + r23 + r25 + r28 + r30 + r31. |
| crc64_13 = | b0 + b3 + b5 + b7 + b8 + b10 + b12 + b16 + b17 + b21 + b24 + b25 + |
| | b29 + b45 + r4 + r5 + r10 + r13 + r14 + r15 + r17 + r24 + r26 + r29 + r31. |
| crc64_14 = | b0 + b1 + b4 + b6 + b8 + b9 + b11 + b13 + b17 + b18 + b22 + b25 + b26 + |
| | b30 + b46 + r5 + r6 + r11 + r14 + r15 + r16 + r18 + r25 + r27 + r30. |
| crc64_15 = | b1 + b2 + b5 + b7 + b9 + b10 + b12 + b14 + b18 + b19 + b23 + b26 + |
| | b27 + b31 + b47 + r6 + r7 + r12 + r15 + r16 + r17 + r19 + r26 + r28 + r31. |
| crc64_16 = | b1 + b4 + b7 + b10 + b11 + b13 + b15 + b16 + b19 + b22 + b23 + b24 + |
| | b26 + b27 + b28 + b48 + r1 + r3 + r4 + r6 + r7 + r8 + r9 + r10 + r11 + r13 + r14 + r18 + |
| | r19 + r29 + r30. |
| crc64_17 = | b2 + b5 + b8 + b11 + b12 + b14 + b16 + b17 + b20 + b23 + b24 + b25 + |
| | b27 + b28 + b29 + b49 + r0 + r2 + r4 + r5 + r7 + r8 + r9 + r10 + r11 + r12 + r14 + r15 + |
| | r19 + r20 + r30 + r31. |
| crc64_18 = | b0 + b3 + b6 + b9 + b12 + b13 + b15 + b17 + b18 + b21 + b24 + b25 + |
| | b26 + b28 + b29 + b30 + b50 + r1 + r3 + r5 + r6 + r8 + r9 + r10 + r11 + r12 + r13 + r15 + |
| | r16 + r20 + r21 + r31. |
| crc64_19 = | b0 + b1 + b4 + b7 + b10 + b13 + b14 + b16 + b18 + b19 + b22 + b25 + |
| | b26 + b27 + b29 + b30 + b31 + b51 + r0 + r2 + r4 + r6 + r7 + r9 + r10 + r11 + r12 + |
| | r13 + r14 + r16 + r17 + r21 + r22. |
| crc64_20 = | b0 + b3 + b4 + b5 + b6 + b7 + b11 + b14 + b15 + b16 + b17 + b19 + b22 + |
| | b27 + b28 + b30 + b31 + b52 + r4 + r5 + r6 + r7 + r8 + r9 + r12 + r13 + r15 + r16 + |
| | r18 + r19 + r20 + r22 + r23 + r27 + r30. |
| crc64_21 = | b0 + b2 + b3 + b5 + b12 + b15 + b17 + b18 + b22 + b26 + b28 + b29 + |
| | b31 + b53 + r0 + r1 + r3 + r4 + r5 + r7 + r8 + r11 + r13 + r21 + r23 + r24 + r27 + r28 + |
| | r30 + r31. |
| crc64_22 = | b2 + b7 + b8 + b13 + b18 + b19 + b20 + b22 + b26 + b27 + b29 + b30 + |
| | b54 + r2 + r3 + r5 + r8 + r10 + r11 + r12 + r16 + r17 + r19 + r20 + r22 + r24 + r25 + |
| | r27 + r28 + r29 + r30 + r31. |
| crc64_23 = | b0 + b3 + b8 + b9 + b14 + b19 + b20 + b21 + b23 + b27 + b28 + b30 + |
| | b31 + b55 + r0 + r3 + r4 + r6 + r9 + r11 + r12 + r13 + r17 + r18 + r20 + r21 + r23 + r25 + |
| | r26 + r28 + r29 + r30 + r31. |
| crc64_24 = | b2 + b3 + b6 + b7 + b8 + b9 + b10 + b15 + b16 + b21 + b23 + b24 + b26 + |
| | b28 + b29 + b31 + b56 + r3 + r5 + r6 + r7 + r9 + r11 + r12 + r13 + r16 + r17 + r18 + |
| | r20 + r21 + r22 + r24 + r26 + r29 + r31. |
| crc64_25 = | b1 + b2 + b6 + b9 + b10 + b11 + b17 + b20 + b23 + b24 + b25 + b26 + |
| | b27 + b29 + b30 + b57 + r1 + r3 + r7 + r8 + r9 + r11 + r12 + r13 + r16 + r18 + r20 + |
| | r21 + r22 + r23 + r25. |
| crc64_26 = | b2 + b3 + b7 + b10 + b11 + b12 + b18 + b21 + b24 + b25 + b26 + b27 + |
| | b28 + b30 + b31 + b58 + r0 + r2 + r4 + r8 + r9 + r10 + r12 + r13 + r14 + r17 + r19 + |
| | r21 + r22 + r23 + r24 + r26. |
| crc64_27 = | b0 + b1 + b2 + b6 + b7 + b11 + b12 + b13 + b16 + b19 + b20 + b23 + |
| | b25 + b27 + b28 + b29 + b31 + b59 + r0 + r4 + r5 + r6 + r13 + r15 + r16 + r17 + r18 + |
| | r19 + r22 + r23 + r24 + r25 + r30. |
| crc64_28 = | b0 + b4 + b6 + b12 + b13 + b14 + b16 + b17 + b21 + b22 + b23 + b24 + |
| | b28 + b29 + b30 + b60 + r3 + r4 + r5 + r7 + r9 + r10 + r11 + r18 + r23 + r24 + r25 + |
| | r26 + r27 + r30 + r31. |
| crc64_29 = | b0 + b1 + b5 + b7 + b13 + b14 + b15 + b17 + b18 + b22 + b23 + b24 + |
| | b25 + b29 + b30 + b31 + b61 + r4 + r5 + r6 + r8 + r10 + r11 + r12 + r19 + r24 + r25 + |
| | r26 + r27 + r28 + r31. |
| crc64_30 = | b3 + b4 + b7 + b14 + b15 + b18 + b19 + b20 + b22 + b24 + b25 + b30 + |
| | b31 + b62 + r0 + r1 + r3 + r4 + r5 + r7 + r10 + r12 + r13 + r14 + r16 + r17 + r19 + r25 + |
| | r26 + r28 + r29 + r30. |
| crc64_31 = | b0 + b1 + b2 + b3 + b5 + b6 + b7 + b15 + b19 + b21 + b22 + b25 + b31 + |
| | b63 + r0 + r2 + r3 + r5 + r8 + r9 + r10 + r13 + r15 + r16 + r18 + r19 + r26 + r29 + |
| | r31. |

The augmenton (i.e 35 or 45) which computes the final remainder may likewise be
consitituted by an array of exclusive-OR gates which may be disposed as indicated
below. In essence the augmenting equations are the same as for the 32-bit CRC
generator 55 with inputs b31 to b0 all tied to zero. since equation (4) = equation (3)
if a₂ = 0 and j = n
Augmenting CRC Equations

| | |
|---|---|
| crcAug_0 = | r0 + r1 + r2 + r3 + r4 + r6 + r7 + r8 + r16 + r20 + r22 + r23 + r26. |
| crcAug_1 = | r1 + r2 + r3 + r4 + r5 + r7 + r8 + r9 + r17 + r21 + r23 + r24 + r27. |
| crcAug_2 = | r0 + r2 + r3 + r4 + r5 + r6 + r8 + r9 + r10 + r18 + r22 + r24 + r25 + r28. |
| crcAug_3 = | r1 + r3 + r4 + r5 + r6 + r7 + r9 + r10 + r11 + r19 + r23 + r25 + r26 + r29. |
| crcAug_4 = | r2 + r4 + r5 + r6 + r7 + r8 + r10 + r11 + r12 + r20 + r24 + r26 + r27 + |
| | r30. |
| crcAug_5 = | r0 + r3 + r5 + r6 + r7 + r8 + r9 + r11 + r12 + r13 + r21 + r25 + r27 + r28 + |
| | r31. |
| crcAug_6 = | r0 + r2 + r3 + r9 + r10 + r12 + r13 + r14 + r16 + r20 + r23 + r28 + r29. |
| crcAug_7 = | r1 + r3 + r4 + r10 + r11 + r13 + r14 + r15 + r17 + r21 + r24 + r29 + r30. |
| crcAug_8 = | r0 + r2 + r4 + r5 + r11 + r12 + r14 + r15 + r16 + r18 + r22 + r25 + r30 + |
| | r31. |
| crcAug_9 = | r0 + r2 + r4 + r5 + r7 + r8 + r12 + r13 + r15 + r17 + r19 + r20 + r22 + |
| | r31. |
| crcAug_10 = | r0 + r2 + r4 + r5 + r7 + r9 + r13 + r14 + r18 + r21 + r22 + r26. |
| crcAug_11 = | r1 + r3 + r5 + r6 + r8 + r10 + r14 + r15 + r19 + r22 + r23 + r27. |
| crcAug_12 = | r2 + r4 + r6 + r7 + r9 + r11 + r15 + r16 + r20 + r23 + r24 + r28. |
| crcAug_13 = | r0 + r3 + r5 + r7 + r8 + r10 + r12 + r16 + r17 + r21 + r24 + r25 + r29. |
| crcAug_14 = | r0 + r1 + r4 + r6 + r8 + r9 + r11 + r13 + r17 + r18 + r22 + r25 + r26 + |
| | r30. |
| crcAug_15 = | r1 + r2 + r5 + r7 + r9 + r10 + r12 + r14 + r18 + r19 + r23 + r26 + r27 + |
| | r31. |
| crcAug_16 = | r1 + r4 + r7 + r10 + r11 + r13 + r15 + r16 + r19 + r22 + r23 + r24 + r26 + |
| | r27 + r28. |
| crcAug_17 = | r2 + r5 + r8 + r11 + r12 + r14 + r16 + r17 + r20 + r23 + r24 + r25 + r27 + |
| | r28 + r29. |
| crcAug_18 = | r0 + r3 + r6 + r9 + r12 + r13 + r15 + r17 + r18 + r21 + r24 + r25 + r26 + |
| | r28 + r29 + r30. |
| crcAug_19 = | r0 + r1 + r4 + r7 + r10 + r13 + r14 + r16 + r18 + r19 + r22 + r25 + r26 + |
| | r27 + r29 + r30 + r31. |
| crcAug_20 = | r0 + r3 + r4 + r5 + r6 + r7 + r11 + r14 + r15 + r16 + r17 + r19 + r22 + |
| | r27 + r28 + r30 + r31. |
| crcAug_21 = | r0 + r2 + r3 + r5 + r12 + r15 + r17 + r18 + r22 + r26 + r28 + r29 + r31. |
| crcAug_22 = | r2 + r7 + r8 + r13 + r18 + r19 + r20 + r22 + r26 + r27 + r29 + r30. |
| crcAug_23 = | r0 + r3 + r8 + r9 + r14 + r19 + r20 + r21 + r23 + r27 + r28 + r30 + r31. |
| crcAug_24 = | r2 + r3 + r6 + r7 + r8 + r9 + r10 + r15 + r16 + r21 + r23 + r24 + r26 + |
| | r28 + r29 + r31. |
| crcAug_25 = | r1 + r2 + r6 + r9 + r10 + r11 + r17 + r20 + r23 + r24 + r25 + r26 + r27 + |
| | r29 + r30. |
| crcAug_26 = | r2 + r3 + r7 + r10 + r11 + r12 + r18 + r21 + r24 + r25 + r26 + r27 + r28 + |
| | r30 + r31. |
| crcAug_27 = | r0 + r1 + r2 + r6 + r7 + r11 + r12 + r13 + r16 + r19 + r20 + r23 + r25 + |
| | r27 + r28 + r29 + r31. |
| crcAug_28 = | r0 + r4 + r6 + r12 + r13 + r14 + r16 + r17 + r21 + r22 + r23 + r24 + r28 + |
| | r29 + r30. |
| crcAug_29 = | r0 + r1 + r5 + r7 + r13 + r14 + r15 + r17 + r18 + r22 + r23 + r24 + r25 + |
| | r29 + r30 + r31. |
| crcAug_30 = | r3 + r4 + r7 + r14 + r15 + r18 + r19 + r20 + r22 + r24 + r25 + r30 + r31. |
| crcAug_31 = | r0 + r1 + r2 + r3 + r5 + r6 + r7 + r15 + r19 + r21 + r22 + r25 + r31. |

FIG. 6 illustrates two further variations The first is that the terminating logic for the augmented CRC (stage 46) is contained in each of the CRC generators 51 to 58 denoted 51a to 58a in FIG. 6) The second is to include the original CRC generator 51 coupled to register 44a to provide feedback bits for all the CRC generators 51a to 58a The modifications reduce the pipelining to a faster one-stage process would result in CRC generation in one clock tick However a great many more XOR gates would be inferred and more critical timing paths created Also, when used for CRC checking, the generated CRC value will be compared to the seed value I(x) producing an error signal in the case of a non-zero difference

1 A method of generating cyclic redundancy code for data packets represented by multi-bit binary signals comprising the steps of
(a) presenting said packets in a succession wherein said packets immediately follow each other without an inter-packet gap therebetween.
(b) computing for each of said packets an intermediate remainder by dividing said packet by a generator polynomial of degree n wherein n is a selected integer.
(c) computing a final remainder by dividing, by the generator polynomial, the product of the intermediate remainder and the term of order n in the generator polynomial,
whereby each packet is padded out with zeros by said computing step (c)

2 A method according to claim 1 wherein the presenting step (a) comprises presenting said packets each in segments consisting of multiplicity of parallel data bytes in an intermediate succession and the computing steps (b) and (c) comprise performing a multiplicity of exclusive-OR operations in respect of selected bits of the said data bytes and said intermediate remainder

3 A generator for the generation of cyclic redundancy code and inter-packet gaps for a succession of data packets, comprising
(i) means for presenting said immediate succession of packets, each in segments consisting of a multiplicity of parallel data bytes,
(ii) at least one cyclic redundancy code generator which includes a register for holding an intermediate remainder and which performs polynomial division of each of the segments by a generator polynomial of degree n where n is a selected integer, and
(iii) augmenting logic disposed downstream of said register for forming a final remainder, said augmenting logic dividing by the generator polynomial the product of the intermediate remainder and the term of order n in the generator polynomial

4 A generator according to claim 3 wherein said cyclic redundancy code generator includes at least one array of exclusive-OR for performing said polynomial division

5 A generator according to claim 4 wherein said augmenting logic comprises an array of exclusive-OR gates
